(19) United States
(12) Patent Application Publication
(10) Pub. No.: US 2012/0270475 A1
(43) Pub. Date: Oct. 25, 2012

(54) APPARATUS AND METHOD FOR DECOATING SOLAR MODULES

(75) Inventors: Pascal Suter, Hunenberg (CH); Adolf Hofer, Lufingen (CH)

(73) Assignee: Komax Holding AG, Dierkon (CH)

(21) Appl. No.: 13/501,010

(22) PCT Filed: Oct. 8, 2009
(86) PCT No.: PCT/EP09/63096

§ 371 Date: Jul. 2, 2012

(51) Int. Cl. H01L 31/18; B24B 7/02; B24B 7/22; B24B 1/00

(52) U.S. Cl. 451/28; 29/760; 451/273; 451/280

(57) ABSTRACT

An apparatus for decoating a solar module includes a rotatable scraper, which is connected to a drive-shaft for driving in rotation and pressing with a pressure-force the scraper onto a surface of the solar module, wherein the rotatable scraper has prongs or teeth with side-faces and end-faces, and wherein the end-faces are embodied as polishing surfaces.

### FIELD

The present invention relates to an apparatus and a corresponding method for the so-called “decoating”, or removal of layers, with this apparatus in the edge-zone of solar modules or thin-film solar modules.

### BACKGROUND

Solar modules or thin-film solar modules require an electrical connection to an external current circuit. The current that is produced on the active surface is typically collected by means of long metal strips at the positive and at the negative pole of the module and conducted out of the module. The connection between the contact surfaces on the module and the metal strips must guarantee a low electrical resistance over the useful life of the module.

Copper-indium-selenium, copper-indium-diselenide, or copper-indium-disulphide (CIS), or copper-indium-gallium-selenium, copper-indium-gallium-diselenide, or copper-indium-gallium-disulphide (CIGS) thin-film technology is known for the high efficiency that can be attained. Typically in this technology, a metallic layer is applied to a glass substrate, followed by a CI(G)S absorber layer and the transparent conductive layer (TCO layer, wherein TCO stands for “transparent conductive oxide”). This TCO layer and the absorber layer are usually removed again at the plus and minus poles, so that the metallization can be contacted directly and with low resistance.

Removal of the TCO and the absorber layer must take place as completely as possible but without damage to the metalizing layer. The resulting cleaned surface must be bounded by as sharp edges as possible, since active surface is otherwise lost.

In addition to this removal, which is referred to as “contact-decoating”, the edge-zone of the thin-film solar module can be freed from all layers that have been applied to create electrical insulation from the surroundings, and to create, for example, optimal conditions for the application of sealing material. This zone-decoating is less demanding and can be attained by polishing, but can also in principle be performed by the same processes as are also used for the contact-decoating.

According to the state of the art, the following process has established itself for contact-decoating or edge-decoating:

a) The layers that are to be removed are scraped off with a sharp-edged glass or metal tool. This process can be mainly considered as a cleaning method that is applied manually or on laboratory scale. Attempts at automation are costly and result in a relatively long processing time, because attainment of the desired final depth of scraping must be subdivided into several processing steps.
b) With sandblasting, the layers to be removed are blasted with a blasting medium and thereby removed. Disadvantageous with this method, however, is that an optimal edge-sharpness cannot be attained, and there is also the risk of the metallization being partly damaged. Furthermore, disposal or recycling of the used blasting medium is cost-intensive. Under certain circumstances, disposal as hazardous waste or even toxic waste is required, and recycling of the blasting medium requires its separation from the removed substances.
c) The international publication WO-A2-2008/120102 discloses an ablation, i.e. removal of the layers that are to be removed by heating with a laser. However, this process is very costly.
d) International Publication WO-A1-2008/107087 discloses an apparatus for brushing off the layers that are to be removed, for example through the use of brushes with bristles of steel. However, disadvantageous with this method is that, if the steel bristles are harder than the material of which the metallization is composed, the steel bristles can damage the metallization. Also disadvantageous is that the removed material can become lodged between the bristles and smeared on the metallization. Further disadvantageous is that the bending of the bristles prevents, or at least hinders, a precise creation of an edge as well as precise attainment of the desired depth of processing.

### SUMMARY

The purpose of the present invention is to provide an apparatus, and a corresponding method that makes use of this apparatus, with which a high accuracy can be attained, decoating of solar modules is generally optimized—through, for example, in particular, less tool-wear occurring, the processing time is shortened, and the costs are thereby reduced.

The purpose is fulfilled by the conception and embodiment of an apparatus with a rotatable scraper.

A rotatable scraper according to the invention is preferably embodied in the form of a cylinder, or cylindrical tube, and preferably has flattened prongs or teeth. These prongs or teeth can, for example, be formed simply through recesses in the body of the cylinder or cylindrical tube.

The prongs or teeth are preferably flattened on their end-faces, i.e. they form a surface that stands perpendicular to the axis of the rotatable scraper. These flattened end-faces are preferably formed as polished surfaces, which—quasi in one single work process—polish off the material surface which has been processed by the prongs or teeth, i.e. they smooth or remove material residues down to the depth of the metallization, but at the same time also serve to align the rotatable scraper on the material surface that is to be processed.

The latter alignment of the rotatable scraper on the material surface that must be processed is preferably realized through the rotatable scraper being mounted in a ball-and-socket joint or universal joint. By this means it is assured according to the invention that the rotatable scraper adapts to a not exactly plane, vertical, alignment of the solar module, and compensates any material unevennesses, or even deliberately embodied concavities. The rotatable scraper is preferably moved at high rotational and lateral speed over the layers that are to be processed. The relationship between rotational and lateral speed determines how often a point on the layers that must be processed is processed by a scraper-edge.

The torque-transmitting connection between the drive-shaft and the rotatable scraper is, as said, preferably realized with a ball-and-socket joint or universal joint. In the case of a ball-and-socket-joint, preferably a connecting pin is inserted through a receptacle of the rotatable scraper and a corresponding drilled hole in the drive-shaft. The receptacle of the rotatable scraper preferably has an elongated hole, such that the connecting pin is mounted with play, and a swivelability of the rotatable scraper results, at the same time as transmission of the torque is assured.

An optional variant embodiment of the torque-transmitting connection by means of a ball-and-socket-joint foresees slots in the ball-head, into which couplers on a hemispherical-shaped receptacle of the rotatable scraper can be inserted. The hemispherical receptacle of the rotatable scraper is fastened onto the ball-head preferably with a hollow and part-spheroidal nut, so that a guided transmission of the contact-pressure of the drive-shaft onto the rotatable scraper, as well as a guided swivelability of the rotatable scraper, are assured, which is preferably possible in all directions.

In principle and alternatively, a swivelable connection between the drive-shaft and the rotatable scraper is possible, which functions entirely by friction. However, lying within the scope of the disclosure of the present application are rigid, non-swivelable connections between the drive-shaft and the rotatable scraper, but which then, however, require an exact alignment of the solar module to the rotatable scraper.

Alternatively realizable is also a variant embodiment of an apparatus for decoating solar modules according to the invention, in which the solar module, clamped on a movable slider, is moved past a linearly locationally fixed, but rotatable, scraper. Furthermore, optionally, an apparatus for decoating solar modules is conceivable in which the said slider is movable in opposite direction to the linear movement of the rotatable scraper, so that particularly high processing speeds, and hence particularly short processing operations, result.

The prongs or teeth of the rotatable scraper are preferably arranged in such manner that they sharpen themselves through the processing. A rotatable scraper according to the invention preferably has 6-12 prongs or teeth, which form an external diameter that corresponds to the processed surface. The side-faces of the prongs or teeth are preferably aligned radially, and form an angle with the end-faces that lies in a range of 50 to 130 degrees, but which preferably has a value of approximately 90 degrees. The smaller this angle, the more aggressive the scraping behavior.

The side-faces of the prongs or teeth of the rotatable scraper can, however, also be aligned non-radially. Depending on the chipping behavior of the material of the surfaces that are to be processed, this can be advantageous for its removal. Further possible is to provide a suction apparatus externally on the rotatable scraper or integrated internally in the axis of rotation.

The rotatable scraper is preferably driven by a drive-shaft, and the connection that transmits the torque is, as already stated, preferably a ball-and-socket joint or universal joint. The drive-shaft preferably presses the rotatable scraper onto the material surfaces that must be processed with a constant contact-pressure. This constant contact-pressure can be generated by, for example, pneumatic cylinders.

However, a further preferred variant embodiment of an apparatus for decoating solar modules according to the invention foresees that the pneumatic cylinder can vary the pressure-force. Thereby is assured in every case that changing counterpressure—caused, for example, by different material thickness or different material quality of the surfaces that are to be processed—does not cause a processing surface to be created with differing processing depth.

A preferred variant embodiment of a rotatable scraper according to the invention foresees that the material of which the rotatable scraper is made is in every case harder than the material of the layers that are to be processed. However, it is also further preferable for the hardness of the material from which the rotatable scraper is manufactured to remain below the hardness of the material of the metallization, so that damage to the latter is avoided as far as possible. Materials that can also be considered for the rotatable scraper according to the invention are, for example, unalloyed or low-alloy steel, copper, copper-bronze, brass, copper-tungsten alloys, and titanium. Also conceivable is a softer base-matrix filled with particles of the said materials.

With suitable selection of material, through contact with the harder metallization, wear of the rotatable scraper occurs mainly at the polishing surfaces. During operation, the scraper-edges are thereby automatically sharpened. The scraper geometry remains preserved when the rotatable scraper becomes worn.

The polishing surfaces on the end-faces that stand perpendicular to the axis of the rotating scraper can be separately formed by application of a corresponding material as polishing surface. Preferable, however, is for the entire rotating scraper to be made of a single material such as, for example, those that were stated above. The material, the alloy, or the base-matrix can optionally be embodied as a carrier material to which polishing particles are added.

In a preferred variant embodiment of an apparatus for decoating solar modules according to the invention, it is foreseen that the rotatable scraper is operable counterclockwise as well as clockwise. This can result in advantages during processing as well as guarantee symmetry of wear and self-sharpening.

As already stated, a possible parameter for controlling or monitoring the processing operation with an apparatus for decoating solar modules is the contact-pressure of the rotatable scraper. Further parameters are the rotational speed of the rotatable scraper or the rotatable speed of the drive-shaft, the torque of the drive, or the lateral speed. It is preferable for these parameters to be captured, preferably with the aid of a computer, and, for example, via a torque limiter, an undesired scraping of the metallization to be additionally ruled out.

A further measure for avoiding damage to the metallization according to the invention is to place the metallization under voltage while it is being processed. If the rotatable scraper comes into electrical contact with the metallization, this causes a current impulse, which can be used as a signal—for example for a stop, a message, or for an automatic reduction of the contact-pressure in the pneumatic cylinder or pneumatic cylinders, which presses or press the rotatable scraper onto the surfaces that must be processed. Also conceivable is, or are, one or more contact finger(s) that follow the rotatable scraper and on bare, contact-giving metallization conduct a current impulse for the generation of a signal as stated above.

The scraping surfaces can be optionally equipped with reversible cutting plates, i.e. cutting-material carriers with a plurality of cutting edges which can be screwed or wedged into a holding apparatus which is provided for this purpose and, upon wear of a cutting edge, are released, or turned, out of the holding apparatus, and screwed or wedged in again.

An apparatus for decoating solar modules according to the invention or a process with a corresponding apparatus brings the following advantages:

The apparatus is relatively compact and inexpensive.

The rotatable scraper is embodied self-sharpening and thereby guarantees long tool service lives.

The processing process results in a high edge-precision between the processed and the unprocessed zone.

The processing process is protective and avoids damage to the metallization to the greatest possible extent.

The apparatus compensates unevennesses or different material thicknesses,

The apparatus offers an inline process control, preferably computer aided.

### DESCRIPTION OF THE DRAWINGS

The invention is explained in greater detail symbolically and exemplarily by reference to figures. The figures are described interrelatedly and overall. They present diagrammatic and exemplary illustrations and are not true to scale, also not with regard to the relations between the individual components. Identical reference symbols indicate identical components, reference symbols with different indices indicate functionally identical, or similar, components.

FIG. 1 a diagrammatic illustration of a thin-film solar module;

FIG. 2 a diagrammatical detail representation of a rotatable scraper according to the invention;

FIG. 3 a further diagrammatical detail representation of the rotatable scraper according to the invention from FIG. 2;

FIG. 4 a further diagrammatical detail representation of the rotatable scraper according to the invention from FIG. 2 and/or FIG. 3;

FIG. 5 a diagrammatical detail representation of the rotatable scraper according to the foregoing figures and a shaft-drive according to the invention;

FIG. 6 a diagrammatical detail illustration of an alternative variant embodiment of a shaft drive according to the invention; and

FIG. 7 a diagrammatic and three-dimensional detail illustration of a decoating apparatus according to the invention.

### DETAILED DESCRIPTION OF THE INVENTION

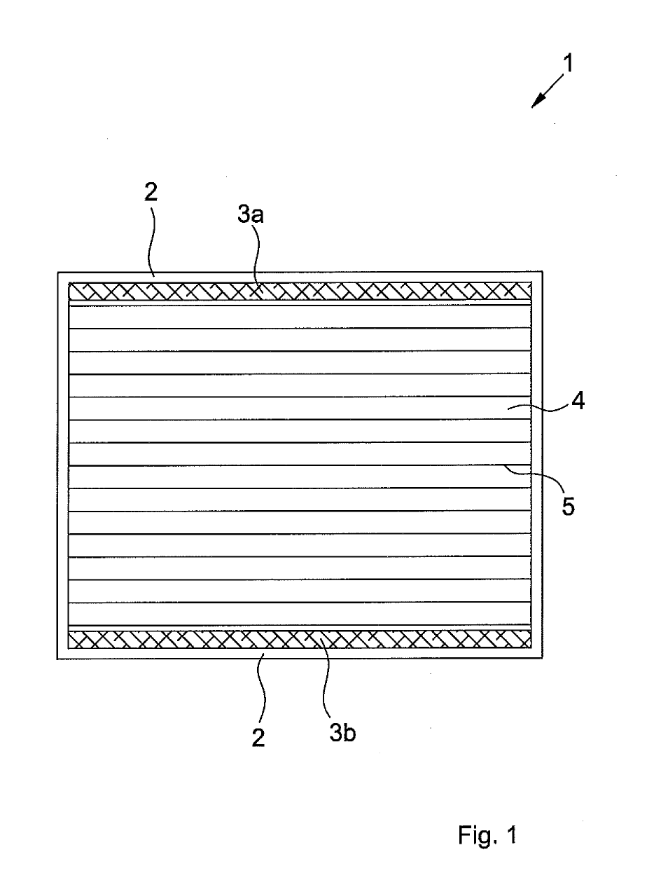

FIG. 1 shows a diagrammatical illustration of a thin-film solar module 1, or also generally of a solar module 1, which, in the finished processed state, has a decoated edge-zone 2; two decoated contact-zones 3a and 3b; individual solar cells, arranged side-by-side, of which only one is exemplarily designated as solar cell 4; as well as the laser scribes that bound the individual solar cells, of which also exemplarily only one laser scribe 5 is designated. Laser scribes are separations that are usually used in solar cells which are created by laser-engraving, laser-etching, or laser-marking. They bound the individual solar cells and serve the internal series-connection of the individual solar cells.

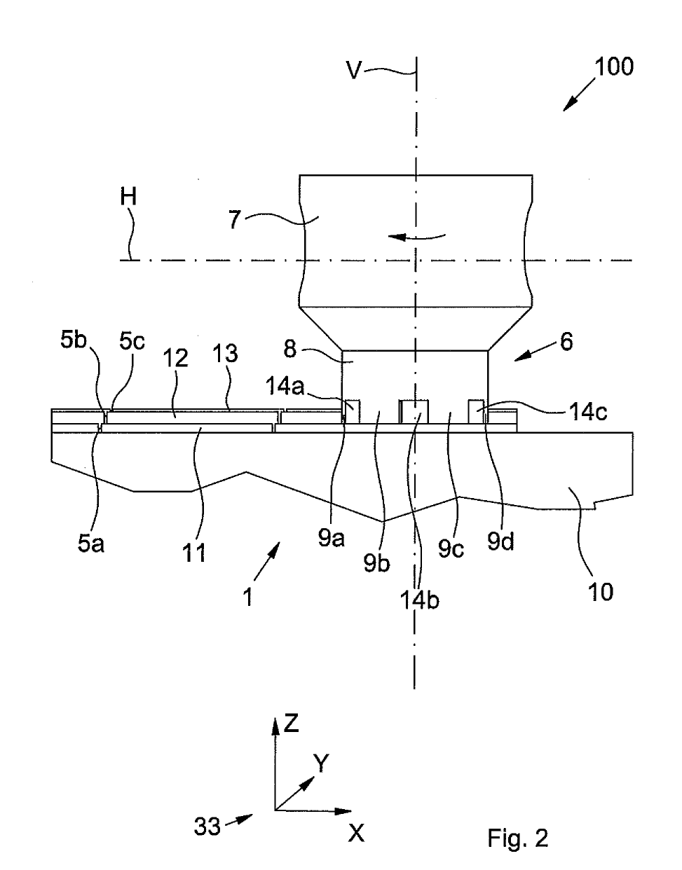

FIG. 2 shows a diagrammatical illustration of a rotatable scraper 6 according to the invention, as it is used in an only indicated decoating apparatus according to the invention 100 for decoating solar modules 1. The solar module 1 consists essentially of a carrier plate 10, which is usually of glass or a glass substrate, a metallization 11 which is applied to this carrier plate 10, an absorber layer 12 which is also applied to this metallization 11, and an uppermost TCO layer 13. The metallization 11, the absorber layer 12, and the TCO layer 13 are interspersed by laser scribes 5a-5c.

The rotatable scraper 6 has a receptacle 7 and a scraper-head 8, in which, through recesses 14a-14c, out of the preferably hollow scraper-head 8, prongs, or teeth, 9a-9d, are formed. The rotatable scraper 6 is rotated corresponding to the arrow about an axis which approximately corresponds to a vertical V, and which simultaneously moves linearly perpendicular to the plane of the drawing along an axis Y of a coordinate system 33, so that the absorber layer 12 and the TCO layer 13 are scraped away over the width of the external diameter of the scraper-head 8. The coordinate system 33 is, in relation to the two-dimensional illustration of the decoating apparatus 100 according to the invention, or of the rotatable scraper 6 according to the invention, only to be understood symbolically, in that an axis X of the coordinate system 33 corresponds approximately to a horizontal H, an axis Z of the coordinate system 33 approximately to the horizontal V, and the axis Y of the coordinate system 33 is not aligned diagonally to the side, but vertically into the plane of the drawing, or simultaneously perpendicular to both the vertical V and the horizontal H.

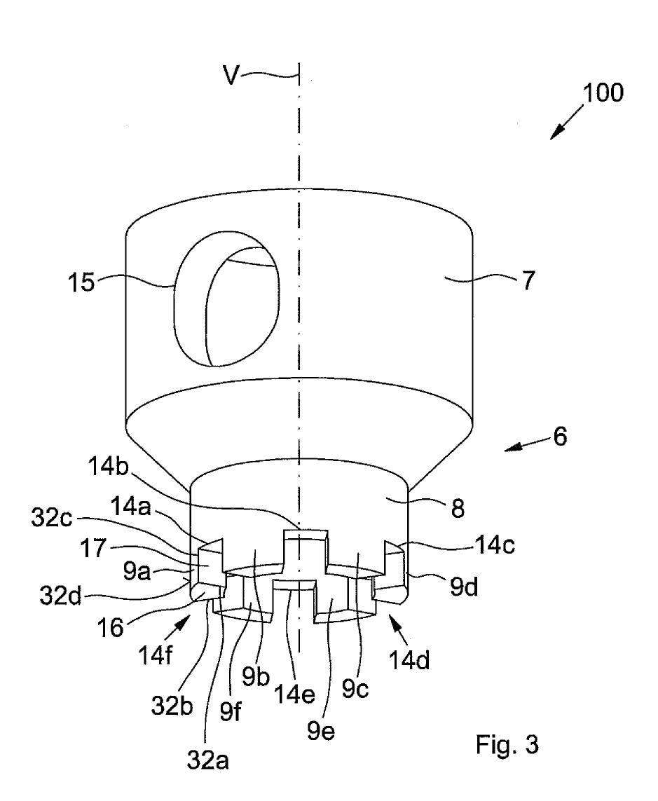

In FIG. 3, the rotatable scraper 6 of FIG. 2 is illustrated in greater detail and three-dimensionally, so that now six prongs or teeth 9a-9f are visible, which are formed by recesses 14a-14f. In the interest of simplicity, shown exemplarily only on the prong or tooth 9a is that each of the prongs or teeth 9a-9f embodies an end-face 16 and a side-face 17. The prong or tooth 9a therefore has four scraping-edges 32a-32d, one scraping-edge 32a between the end-face 16 and the side-face 17, a further scraping-edge 32b between the end-face 16 and a back-facing side-face, which is not more closely identified, but is identical and opposite to the side-face 17, and two scraper-edges 32c and 32d, formed from the side-faces and the external diameter of the scraper-head 8. The end-face 16 is preferably embodied as a polishing surface. The arrangement of prongs and teeth 9a-9f that is illustrated is self-sharpening, and processes the solar module both in the case of a scraper that is rotatable counterclockwise as well as a scraper that is rotatable clockwise.

The holder 7 preferably has an elongated hole 15 for a connecting pin which will be shown further below.

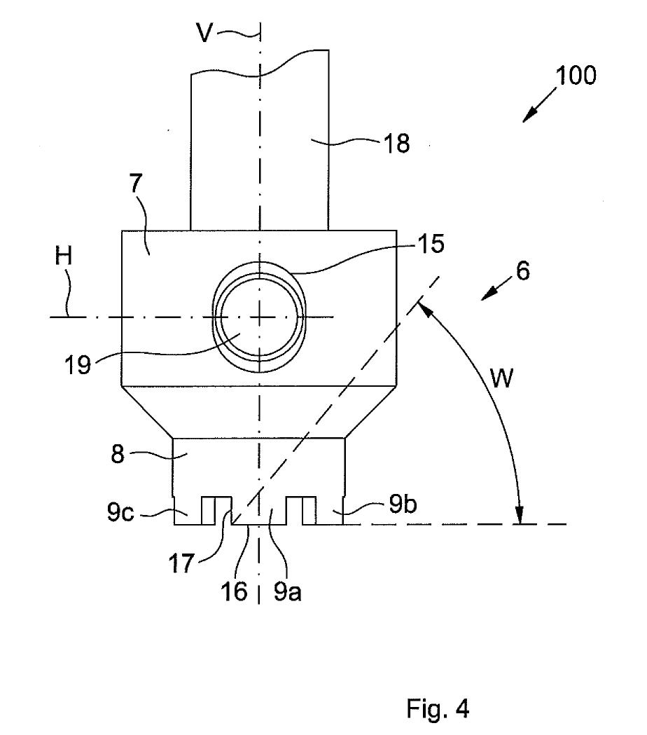

FIG. 4 again shows the rotatable scraper 6 according to the invention from the foregoing FIGS. 2 and 3, now however with a drive-shaft 18 connected by means of a connecting pin 19, in that the connecting pin 19 is arranged in a drilled hole 31 in the drive-shaft 18. Through the connecting pin 19 being simultaneously inserted in the elongated aperture 15, two swivelabilities of the rotatable scraper 6 on the drive-shaft 18 are possible. The first swivelability turns about an axis that projects approximately perpendicular to the plane of the drawing or to an axis which stands approximately perpendicular to the vertical V, and the second swivelability turns about the horizontal H, within the play that the elongated hole 15 provides in the vertical V.

To secure the connecting pin 19, it can be inserted with press fit into the drilled hole 31, a variant embodiment of a connecting pin is, however, also possible which has at one end a collar and at another end a drilled hole for a split-pin.

FIG. 4 also indicates that between the end-face 16 and the side-face 17 of the prong or tooth 9a, an angle W can also be formed, which can be acute, right-angled, or obtuse, and therefore different scraper geometries can find application in different rotatable scrapers 6. The angle W can lie in a range of 50-130 degrees, but is preferably about 90 degrees. The more acute the angle W, the more aggressive it allows the scraping behavior of the rotatable scraper 6 to be.

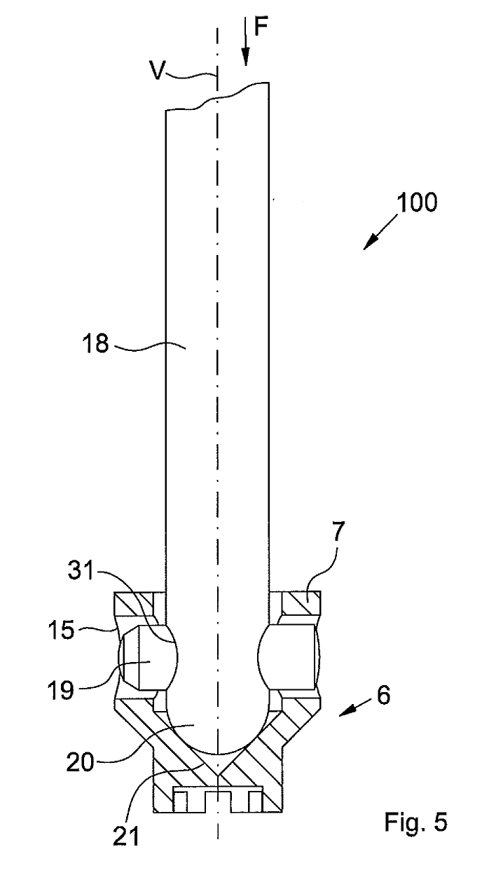

FIG. 5 shows the swivelable connection of FIG. 4 between the rotatable scraper 6 and the drive-shaft 18 in a partially cut-away illustration, so as to make visible the insertion of the connecting pin 19 into the elongated hole 15, in such manner that a swivelability of the rotatable scraper 6 about an axis projecting from the drawing plane—corresponding to the coordinate axis Y—or about an axis standing perpendicular to the vertical V and simultaneously to the coordinate axis Z is possible.

A pressure-force F, which acts along the vertical V, is transmitted via a ball-head 20 of the drive-shaft 18 onto a socket or recess 21 of the rotatable scraper 6.

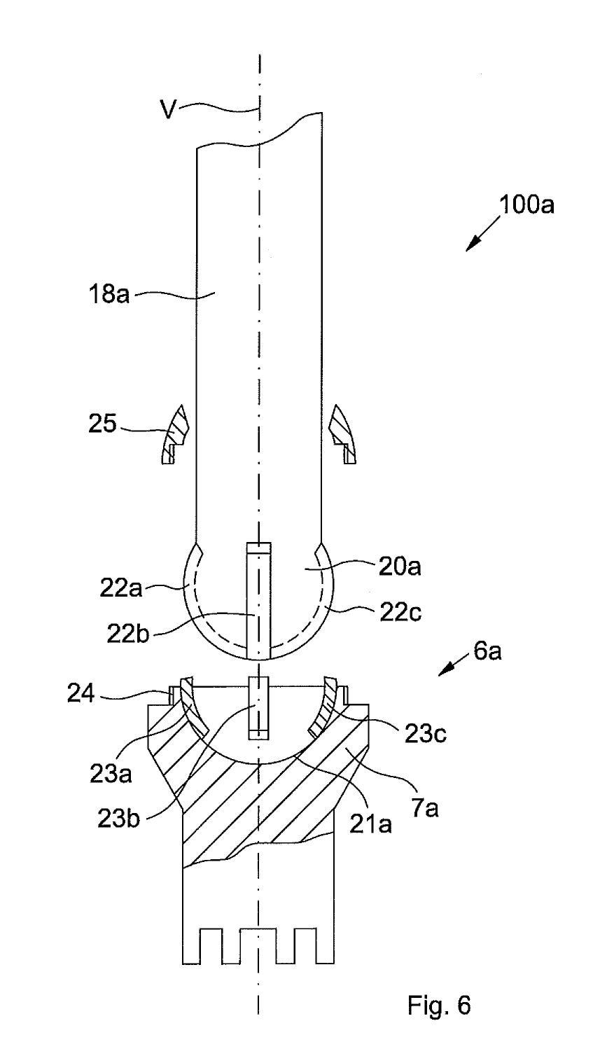

FIG. 6 shows a further variant embodiment, still according to the invention, of a swivelable connection between a rotatable scraper 6a and a drive-shaft 18a. This optional type of connection therefore results in a further variant embodiment according to the invention of an apparatus 100a for decoating solar modules. The drive-shaft 18a has a ball-head 20a, into which preferably four or even more slots are worked, of which in this view slots 22a-22c are visible. Insertable in these slots 22a-22c are couplers 23a-23c, which are arranged mirror-image to the slots 22a-22c in a hemispherical recess 21a.

The couplers 23a-23c are shown rectangular in plan view, see in particular the coupler 23b. The result is a swivelability of the rotatable scraper 6a to the extent to which the rectangular form of the couplers 23a-23c is long and wide, or with how much play the couplers 23a-23c sit in the slots 22a-22c. In this manner, a deliberately limitable swivelability of the rotatable scraper 6a can be realized. Should this not be desired, a free swivelability of the rotatable scraper 6a can be attained through round couplers 23a-23c or also through hemispherical couplers 23a-23c, the latter also sitting preferably in corresponding hemispherical slots 22a-22c.

Furthermore, a receptacle 7a of the rotatable scraper 6a has a thread 24, onto which a hollow and part-spheroidal nut 25 can be screwed. The advantage of a connection as illustrated here between the drive-shaft 18a and the rotatable scraper 6a is a swivelability that is free in every direction, but also guided, at the same time as certain transmission of the torque to the drive-shaft 18a.

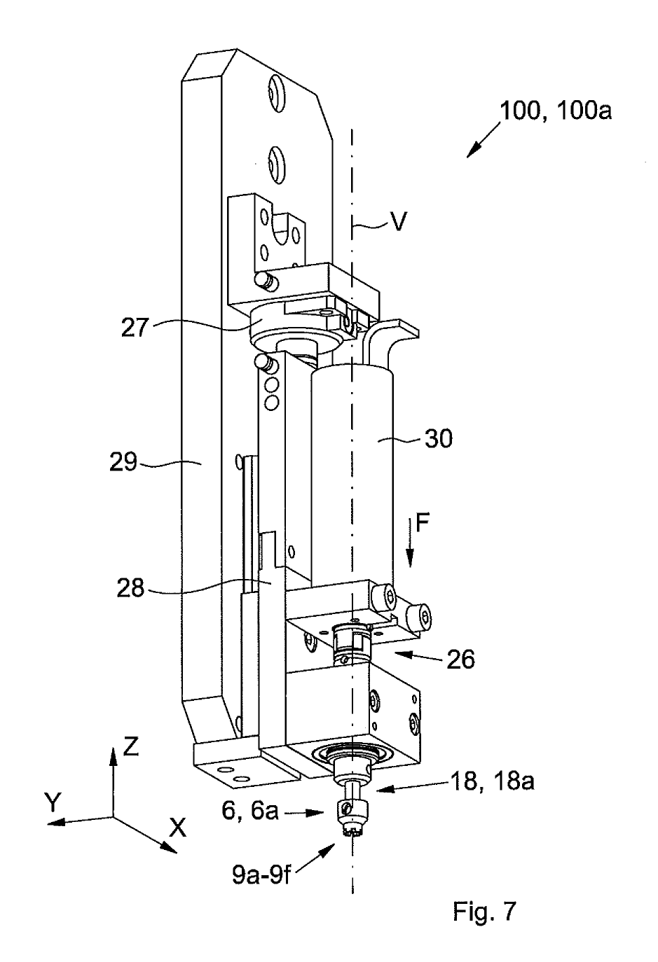

Illustrated in FIG. 7 is the decoating apparatus 100 or 100a according to the invention, depending on whether the swivelable connection between the drive-shaft 18 or 18a is realized with the rotatable scraper 6 or 6a and universal joint according to FIGS. 4 and 5, or the ball-and-socket joint according to FIG. 6. The drive-shaft 18 or 18a is connected by means of a clutch 26 to a drive 30, and at the same time has applied to it by a cylinder 27 a pressure-force F along the vertical V or the coordinate axis Z. Furthermore, the apparatus 100 or 100a has a vertical slider 28 and a horizontal slider 29, which, for the purpose of raising and lowering the complete apparatus 100 or 100a, are preferably fastened to an X-Z system. As already stated, it is, however, also possible, optionally or additionally, to move a slider for accepting the solar module, which is not shown in greater detail, movably guided past the apparatus 100 or 100a.

A preferred processing sequence with an apparatus 100 or 100a according to the invention for decoating solar modules 1 comprises the following steps:
a) Fixing the solar module 1 in a fastener relative to the apparatus 100 or 100a;
b) Setting the rotatable scraper 6 or 6a into rotation—preferably selectably counterclockwise or clockwise—about an axis which approximately corresponds to the vertical V or the coordinate axis Z;
c) Lowering of the rotatable scraper 6 or 6a onto the surface of the upper TCO layer 13 of the solar module 1. so that the end-faces 16 touch the surface of the upper TCO layer 13 and thereby the rotatable scraper 6 or 6a aligns itself on this surface;
d) Application to the rotatable scraper 6 or 6a of the pressure-force F in approximate direction of the vertical V or of the vertical coordinate axis Z;
e) Moving the rotatable scraper 6 or 6a in approximately the direction of at least a horizontal coordinate axis X by moving the horizontal slider 29 or/and by moving the fastener mentioned in Step a), which fixes the solar module 1 relative to the decoating apparatus 100 or 100a.

In accordance with the provisions of the patent statutes, the present invention has been described in what is considered to represent its preferred embodiment. However, it should be noted that the invention can be practiced otherwise than as specifically illustrated and described without departing from its spirit or scope.

1-13. (canceled)

14. An apparatus for decoating a solar module comprising:
a rotatable scraper configured to be driven in rotation by a drive-shaft and to be pressed onto a surface of the solar module with a pressure-force applied by the drive-shaft, wherein the rotatable scraper has a plurality of prongs or teeth each with a side-face and an end-face, and wherein the end-faces of the prongs or teeth are formed as polishing surfaces for contacting the solar module surface.

15. The apparatus according to claim 14 including a joint swivelably connecting the rotatable scraper with the drive-shaft wherein the end-faces contact the solar module surface to self-align the rotatable scraper on the surface of the solar module.

16. The apparatus according to claim 15 wherein the joint is a universal joint having a connecting pin inserted into an elongated aperture formed in the rotatable scraper.

17. The apparatus according to claim 15 wherein that the joint is a ball-and-socket joint having a ball-head with slots into which couplers of a receptacle of the rotatable scraper are inserted.

18. The apparatus according to claim 14 wherein the solar module is fastened to a slider, which slider moves the solar module in guided manner past the rotatable scraper.

19. The apparatus according to claim 14 wherein each of the end-faces forms with an adjacent one of the side-faces an angle which lies in a range from 50 to 130 degrees.

20. The apparatus according to claim 14 wherein each of the end-faces forms with an adjacent one of the side-faces an angle which is approximately 90 degrees.

21. The apparatus according to claim 14 including a pneumatic cylinder applying the pressure-force to the rotatable scraper through the drive-shaft.

22. The apparatus according to claim 21 wherein the pneumatic cylinder applies the pressure-force as a variable pressure-force to maintain a constant contact-pressure of rotatable scraper on the solar module surface.

23. The apparatus according to claim 14 wherein the rotatable scraper is formed of a material that is harder than materials of an absorber layer and a TCO layer on the surface of the solar module, and is softer than a material of a metallization on the surface of the solar module.

24. The apparatus according to claim 14 wherein the rotatable scraper can be driven by the drive-shaft counterclockwise and clockwise.

25. The apparatus according to claim 14 wherein the rotatable scraper is rotated by a torque limited drive connected to the drive-shaft.

26. The apparatus according to claim 14 wherein there is a metallization on the surface of the solar module and when the metallization is connected to a voltage source and is contacted by the rotatable scraper, a signal for reducing the pressure-force is generated.

27. The apparatus according to claim 14 including a reversible cutting plate arranged on each of the side-faces of the prongs or teeth.

28. A method for decoating a solar module with the apparatus according to claim 14 comprising the steps of:
a) fixing the solar module in a fastener relative to the apparatus;
b) rotating the drive-shaft and the rotating scraper about a vertical or a vertical coordinate axis;
c) lowering of the rotatable scraper onto the solar module surface at an uppermost TCO layer of the solar module and contacting the uppermost TCO layer with the end-faces;
d) applying to the rotatable scraper the pressure-force in a direction of the vertical or vertical coordinate axis; and
e) moving the rotatable scraper in a direction of at least one horizontal coordinate axis by at least one of movement of a horizontal slider on which the rotatable scraper is mounted and movement of the fastener in which the solar module is fixed.

29. An apparatus for decoating a solar module comprising:
a rotatable scraper having a plurality of prongs or teeth each with a side-face and an end-face, and wherein the end-faces of the prongs or teeth are formed as polishing surfaces;
a drive-shaft;
a swivelable joint connecting the rotatable scraper to the drive-shaft;
a drive rotating the drive-shaft and the rotatable scraper; and
a cylinder applying a pressure-force pressing the end-faces onto a surface of the solar module.

30. The apparatus according to claim 29 wherein the cylinder is mounted on a horizontal slider and a vertical slider is mounted on and movable relative to the horizontal slider, and wherein the rotatable scraper, the drive-shaft, the swivelable joint and the drive are mounted on the vertical slider.
